(19) United States
(12) Patent Application Publication
(10) Pub. No.: US 2008/0115023 A1
(43) Pub. Date: May 15, 2008

(54) SET HARDENED REGISTER

(75) Inventor: Roy M. Carlson, Plymouth, MN (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc., Morristown, NJ (US)

(21) Appl. No.: 11/553,786

(22) Filed: Oct. 27, 2006

(51) Int. Cl. G01R 31/28

(52) U.S. Cl. 714/731

(57) ABSTRACT

A radiation hardened latch and a method of operation. To mitigate SET effects, the latch includes an internally located pulse rejection inverter. The pulse rejection inverter receives an input logic signal, delays it, and compares the delay logic signal to the input logic signal. If the input logic signal and the delayed logic signal are equivalent, the delayed logic signal is allowed to propagate through the pulse rejection inverter. Because the pulse rejection inverter is internally located, SET events that occur upstream or internal to the latch or on clock signaling are mitigated.

### FIELD

The present invention relates generally to the field of radiation hardened microelectronics, and more particularly to a register or a latch that is configured to mitigate single event transient (SET) effects.

### BACKGROUND

Single event transients (SETs) are transient “glitches” that occur when an energetic particle strikes a transistor region in an electronic circuit. Once hit, one or more downstream circuit nodes may erroneously charge or discharge. In digital circuits, this charge or discharge may cause a circuit node to change from a high voltage level to a low voltage level or vice versa. Consequently, an inadvertent change in voltage also changes the logical state of a digital circuit. A temporary change in the logic state of a digital memory circuit such as a latch or register that is only corrected when new data is written to the latch or register on the next clock cycle is known as a soft error or single event upset (SEU). Thus, an SET that causes a memory state change that is not transient causes an SEU.

SETs randomly occur and do not always have an affect on a circuit. For example, even though an energetic particle has deposited charge within a transistor region, it may have no impact on the logical state of the transistor region or downstream circuit nodes (i.e., an energetic particle charging a node that is already at a logical “high” will probably not change the logical state to “low”). Furthermore, some energetic particles do not deposit enough charge to cause the transistor region to sufficiently charge or discharge a circuit node.

Despite this, SET effects are likely to affect a circuit when it is in a vulnerable state, such as when a clock signal changes from one logical state to another (e.g., from high to low or vice versa). Because digital circuits use the clock signal to coordinate operations within the circuit, SETs have an increased likelihood of deleteriously affecting a circuit during these transitions. Accordingly, the more often a clock signal transitions, the more vulnerable a circuit may become to SET effects.

One type of digital circuit in particular that coordinates signals in digital circuitry is a register, which includes one or more data latches. In general, a register receives an upstream combinational logic signal and captures or holds the data for a duration that is associated with the frequency of a clock signal. During the transition of the clock signal a register may transition from a state where the register is continuously sampling new data, to a state where the sampled data is captured and held within the register until the next clock transition. Thus, if an erroneous data state is present on the input of a register at the time when the clock is transitioning from the sample to the hold state the register may capture the erroneous data state instead of the correct data state. This dependency upon the clock signal makes a register particularly susceptible to SETs, particularly if the register is cycled at a high frequency. For example, on technologies with a minimum feature size of 0.25 μm or less, SET induced state upsets can become the dominant SEU mechanism at clock frequencies of approximately 100 MHz or more.

FIG. 1A shows a D-type register 10 that is coupled to upstream combinational logic 12. The register 10 is cycled by a clock signal, which FIG. 1A shows as being provided at a clock input 14. In general, the clock input 14 is coupled to a clock tree that distributes replicated forms of the clock signal (denoted as CLK) and inverse replicated forms of the clock signal (denoted as C̅L̅K̅) to various nodes within the register 10. Although the register 10 is a D-type register, registers and latches, in general, may also comprise a variety of other configurations, such as S/R or J/K.

Internal to the register 10 is a master latch and a slave latch. The master latch receives an input logic signal, captures a logical state of the logical signal, and communicates the captured logical state to the slave latch. Accordingly, the slave latch outputs a latched logic signal that corresponds to the captured logical state. To do this, the master latch comprises inverter 16 and tri-state inverters 17, 18, which are ultimately cycled by the clock signal. Similarly, the slave latch comprises inverters 20, 21 and tri-state inverters 22, 23, which are cycled 180 degrees out of phase with the master latch.

FIG. 1B is a signal line diagram that shows general operation of the register 10. FIG. 1B shows the signals CLK and C̅L̅K̅ (which are generated by CLOCK), as well as an input logic signal at node D, sampled logic signals at nodes X and Y, and latched logic output signal at node Q*. The signal at node D represents data that may be received from upstream combination logic 12; the signals at nodes X and Y represent data that has been captured by the master latch; and the signal at node Q* represents the preferred latched logic signal output. FIG. 1B shows how the master latch captures a logic state. First, when CLOCK is low, inverter 18 is on, and the signal at X tracks the signal at D. When CLOCK is high, inverter 18 is off and inverter 17 maintains the data state captured at the rising edge of CLOCK, which is independent of the signal at D.

Overall, the slave latch operates in a similar manner as the master latch except that the slave latch captures data at the falling edge of CLOCK. On the rising edge of CLOCK, new data is transferred from the master latch to the slave latch and the logic state is output at Q*. At the falling edge of CLOCK, the slave latch captures the logic state of the signal at Y and holds the logic state in the slave latch while CLOCK is low. It should be understood that although FIG. 1B shows the register 10 ultimately capturing the signal at D on the rising edge of CLOCK, a latch may be designed to capture data at a variety of phases of a clock signal. Thus, as an alternative example, FIG. 1C shows a signal diagram of a master latch that captures data at a falling edge of CLOCK

As described above, digital circuits, and registers and latches in particular, are more vulnerable to SETs during clock cycle transitions. FIG. 1D shows that the register 10 is particularly vulnerable to SETs during the rising edge transition of CLOCK During the first rising edge transition of CLOCK, an SET in upstream logic 12 has induced a glitch 25 at D, which has pulled the signal at D low. Because D is low at the first rising edge transition of CLOCK, the master latch captures a low logic state, which ultimately causes Q to output a logic low. Instead of representing a logic high, as Q should (compare to Q*), the latch output signal has become corrupted.

Although SETs are probably the most deleterious during clock cycle transitions, SETs may corrupt and disrupt a register or a latch in other ways. FIGS. 1D-G, for example, show how glitches may inadvertently pull the output signal at Q low. FIG. 1E shows that a glitch 26 on C̅L̅K̅ causes the master latch to inadvertently capture the signal at D; FIG. 1F shows that a glitch 27 at X causes the logical state of the signal at Y to change; and, FIG. 1G shows that a glitch 28 on Y causes the slave latch to output an erroneous value at Q. (see also FIG. 1A, which includes arrows that point to some of the elements that are likely to produce each of the glitches 25-28).

Therefore to insure proper operation and data storage within digital latches, it is desirable to mitigate SETs effects that occur internally, within clock signaling, and on upstream combinational logic.

### SUMMARY

A radiation hardened register is presented. The register comprises a latch that includes: a sampling gate for receiving an input logic signal and a clock signal; an output node for outputting a latched logic signal that corresponds to the input logic signal; and, latching logic, which is configured to latch the input signal at a predetermined phase of the clock signal (e.g., a rising or falling edge of the clock signal). The latching logic comprises a pulse rejection inverter for mitigating upstream or internal SET effects as well as SET effects that occur on the clock signal.

The pulse rejection inverter, in operation, receives a sampled logic signal, delays it, and compares the sampled logic signal to the delayed logic signal. To do this, the pulse rejection inverter may comprise at least one delay gate that has a delay time that is longer than the duration of an SET event. The delay gate may be coupled to a series of stacked FETs, which only allow the delayed logic signal to propagate through the stacked FETs when the sampled logic signal and the delayed logic signal are at an equivalent voltage level.

In another example, a radiation hardened register may comprise a master latch for receiving an input logic signal and a slave latch for outputting a latched logic signal. The master latch includes a pulse rejection inverter that, in operation, delays the input logic signal and compares the delayed logic signal to the input logic signal. The pulse rejection inverter mitigates SET effects by only allowing the delayed logic signal to propagate through the latch when it is at the same voltage level as the input logic signal. The slave latch may also include a pulse rejection inverter, which further mitigates SET events.

As an alternative example, a method of operating a radiation hardened register is also described. The method includes: receiving an input logic signal, sampling the input logic signal at a first phase of a clock signal, delaying the sampled logic signal, comparing the sampled logic signal to the delayed signal, and propagating the delayed logic signal to an output node of the register when the sampled and delayed signal are at an equivalent voltage level.

These as well as other aspects and advantages will become apparent to those of ordinary skill in the art by reading the following detailed description, with reference where appropriate to the accompanying drawings. Further, it is understood that this summary is merely an example and is not intended to limit the scope of the invention as claimed.

### BRIEF DESCRIPTION OF THE DRAWINGS

Certain example embodiments are described below in conjunction with the appended drawing figures, wherein like reference numerals refer to like elements in the various figures, and wherein:

FIG. 1A is a schematic diagram of a prior art register;

FIGS. 1B-C are signal line diagrams that show the operation of the register of FIG. 1A;

FIGS. 1D-G are signal line diagrams that show how SET events disrupt operation of the register of FIG. 1A;

FIGS. 2A-B are respective schematic and signal line diagrams of a pulse rejection inverter that comprises four delay gates, according to an example;

FIGS. 2C-D are respective schematic and signal line diagrams of a pulse rejection inverter that comprises six delay gates, according to an example;

FIG. 3A is a schematic diagram of an example register that receives a delayed logic signal from a pulse rejection inverter;

FIG. 3B is a signal line diagram that shows how the pulse rejection inverter of FIG. 3A mitigates upstream SET events;

FIG. 3C is a schematic diagram of another example register that comprises an internal pulse rejection inverter; and

FIGS. 3D-G are signal line diagrams that show how the register of FIG. 3C mitigates the respective SET events of FIGS. 1D-G.

### DETAILED DESCRIPTION

The described register includes a data latch that comprises an internal pulse rejection inverter for mitigating SET effects. The pulse rejection inverter mitigates these effects by delaying an input logic signal; comparing the input logic signal to the delayed logic signal, and propagating the delayed logic signal when both signals are at a substantially equivalent voltage level. Because the pulse rejection inverter is internally located, it mitigates not only upstream SETs, but also SETs that occur within the latch itself as well as SETs that occur on the clock signal.

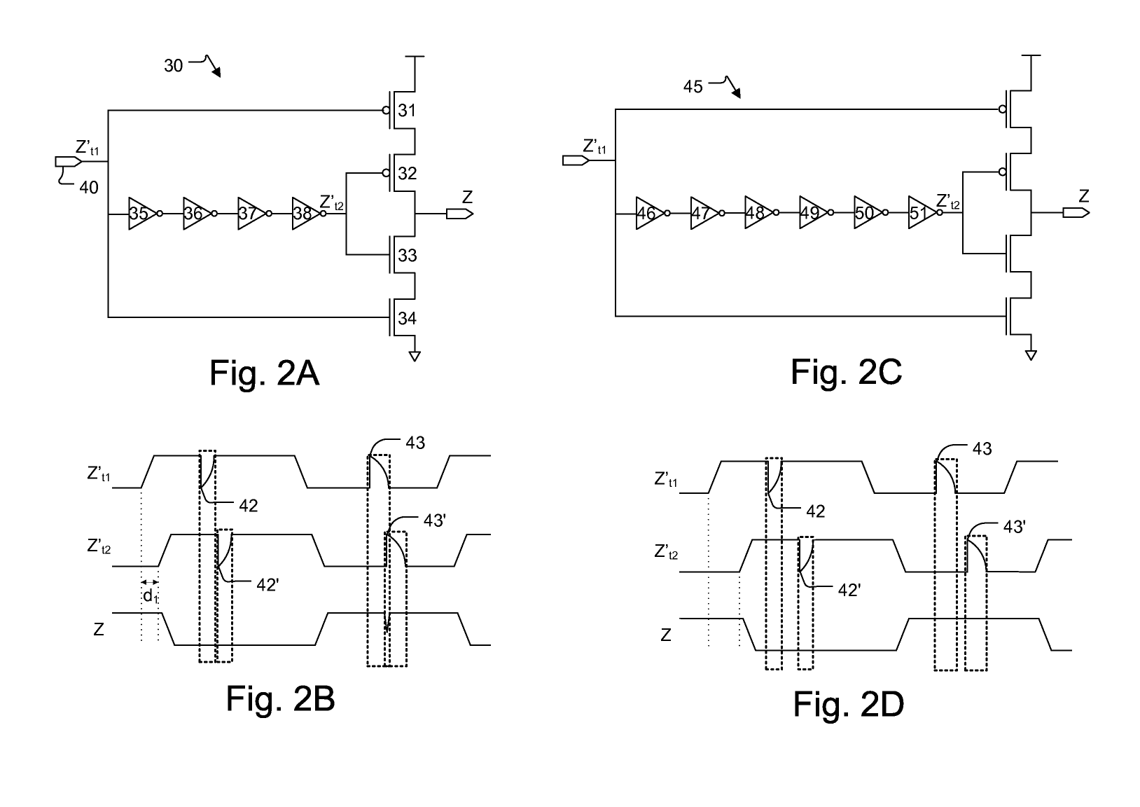

Although its internal configuration is different than that of a conventional inverter, the pulse rejection inverter produces an output that is analogous to that of a conventional inverter; the pulse rejection inverter receives an input logic signal, inverts the input logic signal, and outputs an inverted logic signal. FIG. 2A is a schematic diagram that shows the internal configuration of a pulse rejection inverter 30. The pulse rejection inverter 30 includes a series of stacked FETs 31-34 and a chain of inverting delay gates 35-38. An input terminal 40 of the pulse rejection inverter 30 is coupled to receive an input logic signal Z′ₜ₁. The pulse rejection inverter 30 communicates Z′ₜ₁ to the delay gate 35 and gate inputs of the FETs 31, 34. At the end of the chain of delay gates, the delay gate 38 communicates Z′ₜ₂, a delayed version of Z′ₜ₁, to gate inputs of the FETs 32, 33. The pulse rejection inverter 30 use both Z′ₜ₁ and Z′ₜ₂ to produce an output signal, Z, at a common drain connection of the FETs 32, 33.

FIG. 2B is a signal line diagram that shows the operation of the pulse rejection inverter 30. The cumulative delay time, d₁, associated with the delay gates 35-38, causes Z′ₜ₂ to lag behind Z′ₜ₁. Thus, when Z′ₜ₁ transitions from low to high (or vice versa), Z′ₜ₂ will also do so, but it will be offset by the time d₁. The stacked FETs 31-34 will only allow Z′ₜ₂ to propagate through the pulse rejection inverter 30 when both Z′ₜ₁ and Z′ₜ₂ are at an equivalent voltage level. For example, the gate terminal of FETs 31, 32 need to both go low in order for Z to go high. Alternatively, the gate terminal of FETs 33, 34 need to both go high in order to for Z to go low. Therefore, if Z′ₜ₁ and Z′ₜ₂ are at a different voltage level, Z will float and retain its previous output level.

The pulse rejection inverter 30 uses the delay time d₁ to mitigate SET effects. For example, when a glitch 42 occurs on Z′ₜ₁ the glitch 42′ on Z′ₜ₂ lags behind the glitch 42 by d₁. Thus, because Z will only transition when Z′ₜ₁ and Z′ₜ₂ are at an equivalent voltage, the glitch 42 does not cause Z to transition, and therefore Z maintains the correct output. However, the delay time d₁ should be determined so that glitches on Z′ₜ₁ and Z′ₜ₂ do not overlap and thus propagate to the output signal Z. For example, in FIG. 2B glitches 43 and 43′ have a longer duration than the delay time d₁and ultimately end up propagating to the signal Z.

The duration of a glitch depends on how much charge is typically deposited at a circuit node during an SET. This charge is deposited when an energetic particle passes through a silicon region and a track of hole-electron pairs is deposited. The deposited charge causes an SET event which appears as a transient voltage on the affected circuit nodes. The magnitude of the deposited charge depends on the ion, the ion energy and the path length, and is generally larger for particles with high atomic numbers. The duration of an SET event is in general proportional to the deposited charge and as a result the time duration of the SET event in a given circuit will increase as the atomic number of the particle increases. The probability of a particle strike decreases with increasing atomic number because the flux of particles in outer space decreases with increasing atomic number. Therefore, the amount of delay inserted into the pulse rejection inverter can be selected to reduce the probability of an SET induced SEU to acceptable levels while minimizing the circuit performance loss caused by the added delay. Typically, SET pulse durations can range from approximately 100 ps to 1 ns.

FIG. 2C shows a pulse rejection inverter 45 that includes delay gates 46-51, which have a cumulative delay time d₂. Because the delay time d₂ is longer than d₁, the pulse rejection inverter 45 is able to mitigate glitches 42 and 43 (See FIG. 2D). Note, however, that the delay times d₁ and d₂ affect the overall switching speed of the respective pulse rejection inverters 30, 45. Thus, careful consideration should be given when determining an appropriate delay time of a pulse rejection inverter.

The stacked FETs 31-34 shown in FIG. 2A provide an additional SET hardening benefit in that they may prevent SET's from occurring on the output node of the pulse rejection inverter 30. For example, if Z′ₜ₁ and Z′ₜ₂ are both in a logic low state, the FETs 33 and 34 are non-conducting and output Z is in a logic high state. If a particle strikes either FET 33 or 34, causing it to conduct, the output Z will not be pulled low due to the series connection of two FETs in a non-conducting state. In a similar manner FETs 31 and 32 prevent SETs from occurring on the output node of the pulse rejection inverter 30 when the nodes Z′ₜ₁ and Z′ₜ₂ are both in a logic high state. The SET hardness of the pulse rejection circuit can be further enhanced in an SOI technology by connecting the body terminal of the inner FETs 32 and 33 to the FET source instead of VDD or VSS. The body-source connection prevents a direct path across the drain P-N junction of FET 32 or 33 to VDD or VSS, respectively.

It should be obvious to one skilled in the art that the strategy employed in the pulse rejection inverter can be extended to any CMOS logic gate. First, each input that is to have pulse rejection applied is connected to a chain of delay gates similar to delay gates 35-38 in FIG. 2A to create a delayed version of that input. Then, each FET in the logic circuit that receives an input that is to have pulse rejection applied is replaced with 2 FETs in series. Finally, the gate of one of the two series FETs is connected to the original input, and the gate of the second of the two series FETs is connected to the delayed version of the original input. In this way any function that can be implemented in CMOS transistor logic can be implemented as a pulse rejection logic gate.

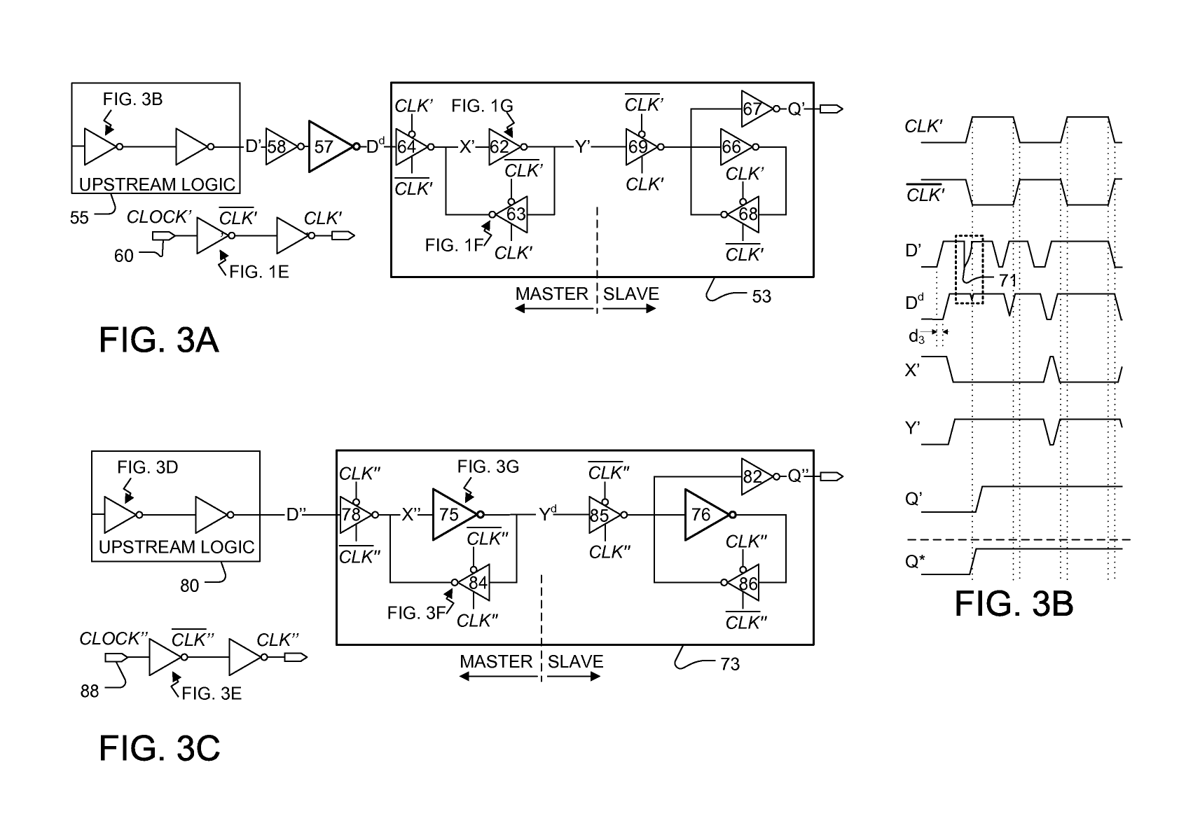

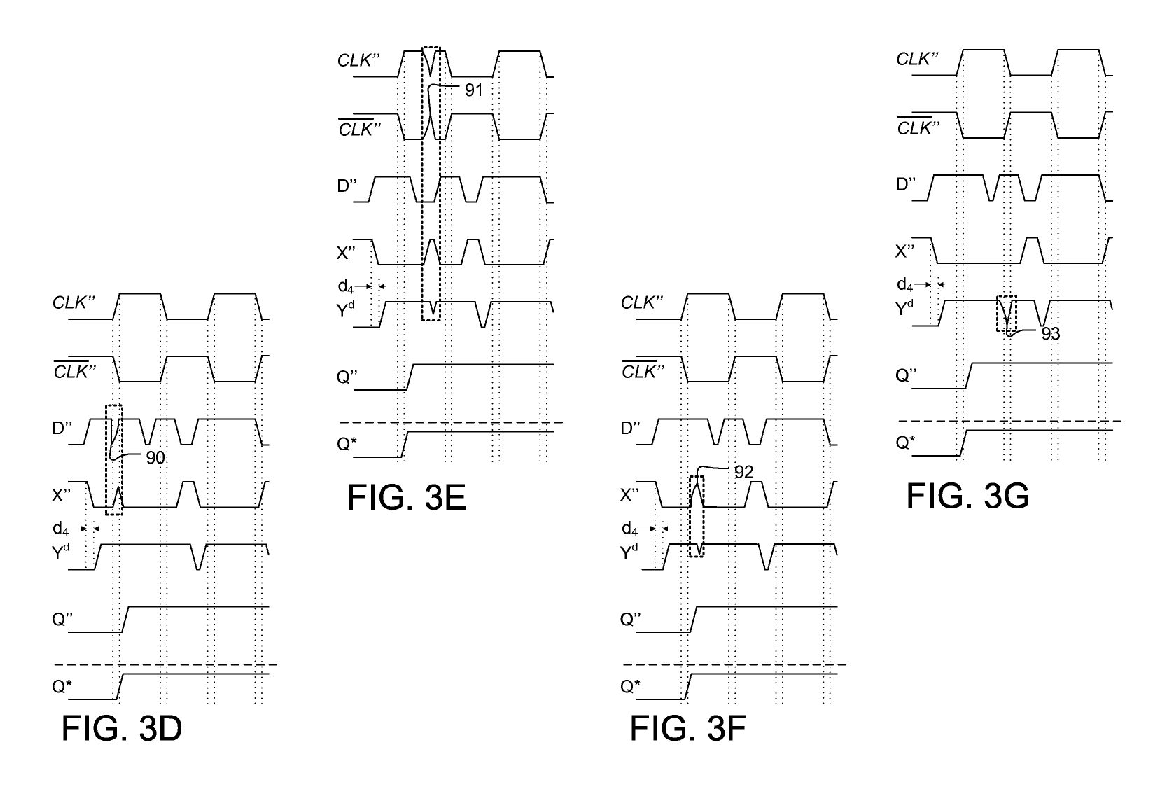

FIG. 3A shows a D-type register 53 that is coupled to upstream combinational logic 55 via a pulse rejection inverter 57 and an inverter 58. The register 53 is cycled by a clock signal, which FIG. 3A shows as being provided at a clock input 60. In general, the clock input 60 is coupled to a clock tree that distributes replicated forms of CLK′ and C̅L̅K̅′̅ (which are generated by CLOCK) to various nodes within the register 53. Although the register 53 is a D-type register, registers and latches, in general, may also comprise a variety of other configurations, such as S/R or J/K. In addition, the tri-state inverters 64, 69 may, in other configurations, be replaced with non-inverting sampling gates. For example a complementary PN pair pass-gate can be used in place of the tri-state inverters 64 and 69.

Internal to the register 53 is a master latch and a slave latch. The master latch receives an input logic signal, captures or samples a logical state of the logical signal, and communicates the sampled logical state to the slave latch. Accordingly, the slave latch outputs a latched logic signal that corresponds to the sampled logical state. To do this, the master latch comprises inverter 62 and tri-state inverters 63, 64, which are ultimately cycled by the clock signal. Similarly, the slave latch comprises inverters 66, 67 and tri-state inverters 68, 69, which are cycled 180 degrees out of phase with the master latch.

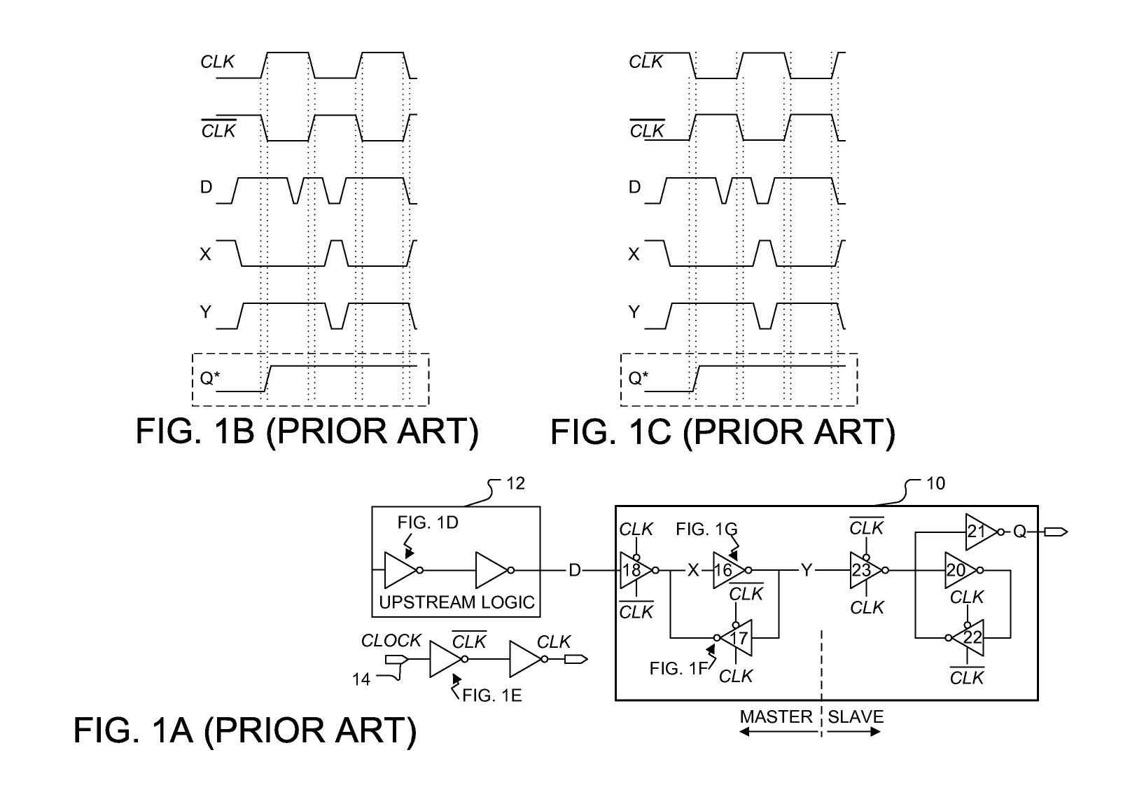

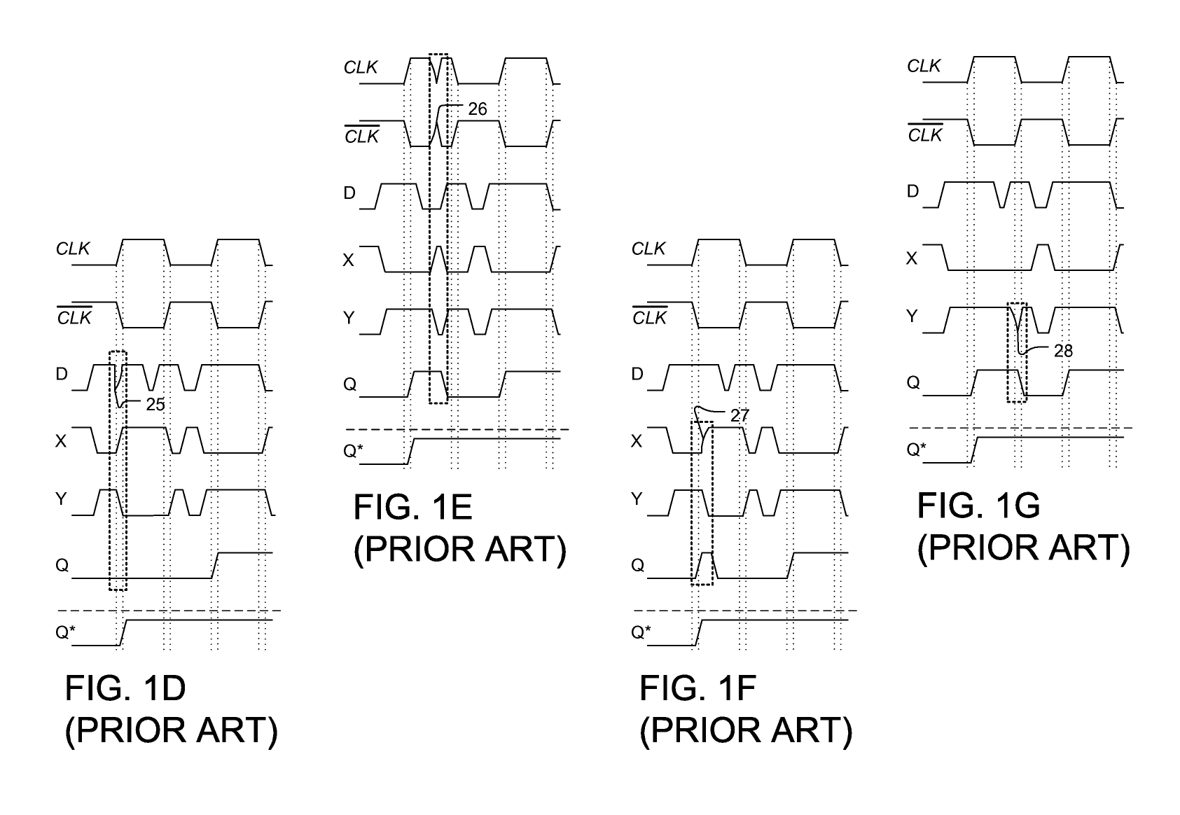

FIG. 3B is a signal line diagram that shows general operation of the latch 53 and how the pulse rejection inverter 57 mitigates single event effects. FIG. 3B shows the signals CLK′ and C̅L̅K̅′̅, as well as an input logic signal at node D′, a delayed logic signal at node D^{d}, sampled logic signals at nodes X′ and Y′, latched logic output signal at node Q′, and the preferred output signal (see FIG. 1B, node Q*). The signal at D′ represents data that may be received from upstream combinational logic 55; the signal at D^{d} is the output of the pulse rejection inverter 57, which has been delayed by a duration d₃, the signals at X′ and Y′ represent data that has been captured by the master latch; and the signal at Q′ represents the output of the latch 53.

FIG. 3B shows how the master latch captures a logic state. First, when CLOCK′ is low, inverter 64 is on, and signal X′ tracks the signal at D^{d}. When CLOCK′ is high, inverter 64 is off and inverter 63 maintains the data state captured at the rising edge of CLOCK′, which is independent of the signal at D^{d}. Overall, the slave latch operates in a similar manner as the master latch except that the slave latch captures data at the falling edge of CLOCK′. On the rising edge of CLOCK′, new data is transferred from the master latch to the slave latch and the logic state is output at Q′. At the falling edge of CLOCK′, the slave latch captures the logic state of the signal at Y′ and maintains this logic state at Q′.

FIG. 3B also shows that the pulse rejection inverter 57 prevents a glitch 71 from propagating to the output Q′. An SET, for example, may have induced the glitch 71 in upstream logic 55. Similar to the output signal Z in FIGS. 2C, 2D, the signal at D^{d} is not substantially affected by glitches that have a duration that is less than or equal to the delay inside the pulse rejection inverter 57. Thus, glitches that occur in upstream logic 55 or inverter 58 are less likely to propagate to the output Q′.

Although the register 53 is hardened against upstream SET events, the register 53 itself is still vulnerable to SETs that occur internally or on the CLK′ and C̅L̅K̅′̅ signals (see FIGS. 1E-G). For example, the register 53 will be substantially vulnerable to the type of glitch shown in FIG. 1E. Therefore, to harden the register 53 against state upsets caused by glitches that occur internal to the register or on the clock signal it is preferable for a pulse rejection inverter to be positioned internally within a latch.

FIG. 3C shows a register 73 that comprises internally located pulse rejection inverters 75, 76. The register 73 comprises a tri-state inverter 78 for receiving an input logic signal, which is supplied from upstream combinational logic 80. The register 73 also comprises an inverter 82 for outputting a latched logic signal that corresponds to the input logic signal. (The tri-state inverters 78, 85 may, in other configurations, be replaced with non-inverting sampling gates.) The pulse rejection inverters 75, 76 are located within the respective latching logic of the master and slave latches. For example, the latching logic of the master latch comprises pulse rejection inverter 75 and tri-inverter 84. Similarly, the latching logic of the slave latch comprises pulse rejection inverter 76, tri-state inverter 86, and inverter 82. Also, similar to the register 53 (see FIG. 3A), the tri-state inverters 78 and 84-86 are coupled to receive CLK″ and C̅L̅K̅″̅, which are supplied by a clock tree that is fed by a clock signal CLOCK″ at an input 88. The latching logic of the master and slave latches uses these clock signals to latch a sampled logic signal (i.e., an input signal that has passed through a sampling gate (e.g., the tri-state inverter 86)) at a predetermined phase of the CLK″ signal (e.g., the rising or falling edge of CLK″).

Each of the pulse rejection inverters 75, 76, in operation, receives a sampled logic signal, delays it, and compares the sampled logic signal to the delayed logic signal. As described with reference to FIG. 2, each of the pulse rejection inverters 75, 76 is configured to allow a delayed logic signal to propagate downstream only when the sampled logic signal and the delayed logic signal are at a substantially equivalent voltage level.

FIG. 3C shows the master latch comprising the pulse rejection inverter 75 and the slave latch comprising pulse rejection inverter 76. The master latch, in operation delays the input or sampled logic signal at node X″ and communicates the delayed logic signal at node Y^{d} to the slave latch. The slave latch receives the delayed logic signal, delays it yet again, and creates the output latched logic signal. However, in alternative examples, more or fewer pulse rejection inverters may be included within a latch. For example, the number of pulse rejection inverters that a particular register comprises may depend on the complexity of the register. Thus, registers that comprise a larger number of SET sensitive nodes may include two or more pulse rejection inverters and registers that are less complex may only require one pulse rejection inverter.

FIGS. 3D-G shows the operation of the register 73 and how it mitigates SET events that occur upstream or internal to the register as well as SET events that occur on the clock signaling. Each of the FIGS. 3D-G show the output of the register 73, at node Q″, and how it is substantially equivalent to the preferred output Q* (see FIG. 1B). Also, and in contrast to the register 53 (see FIG. 3A), the register 73 uses the pulse rejection inverters internally, and thus the internal signal at Y^{d} is offset from internal signal at X″ by a delay d₄. However, similar to the register 53, the internally located pulse rejection inverters mitigate upstream SET events. FIG. 3D shows a glitch 90 on the input signal at node D″ and the pulse rejection inverter 75 preventing the glitch 90 from propagating through the master latch (see in contrast FIG. 1D).

FIG. 3E shows the latch 73 mitigating SET events that occur on C̅L̅K̅″̅. A glitch 91 causes the signal at X″ to go high. However, the pulse rejection inverter 75 prevents the glitch 91 from propagating through the master latch (see in contrast FIG. 1E). The pulse rejection inverter 75 would also mitigate SET events that occur on CLK″.

FIG. 3F shows the latch 73 mitigating other SET events that create a glitch 92 and cause the signal at X″ to go high. The pulse rejection inverter 75 prevents the glitch 92 from propagating through the master latch (see in contrast FIG. 1F).

FIG. 3G shows the latch 73 mitigating SET events that create glitches which are downstream from the master latch. Here, a glitch 93 occurs and causes Y^{d} to go low. However, the pulse rejection inverter 76 prevents the slave latch from latching a low logic level glitch on Y^{d} which would result in Q″ going low (see in contrast FIG. 1G).

A variety of examples have been described above, all of which may use a pulse rejection inverter to mitigate SET effects that occur upstream or internally or on clock signaling. However, those skilled in the art will understand that changes and modifications may be made to these examples without departing from the true scope and spirit of the present invention, which is defined by the claims. Thus, for example, a pulse rejection inverter may be exchanged with a conventional inverter or tri-state inverter to increase the radiation hardness of a variety of digital circuits. Accordingly, the description of the present invention is to be construed as illustrative only and is for the purpose of teaching those skilled in the art the best mode of carrying out the invention. The details may be varied substantially without departing from the spirit of the invention, and the exclusive use of all modifications which are within the scope of the appended claims is reserved.

I claim:

1. A radiation hardened latch, comprising:
a sampling gate coupled to receive an input logic signal and a clock signal;
an output node for outputting a latched logic signal that corresponds to the input logic signal; and
latching logic coupling the sampling gate to the output node, wherein the latching logic is configured to latch the input logic signal at a predetermined phase of the clock signal, and wherein the latching logic comprises a pulse rejection inverter for mitigating upstream and internal single event transient effects.

2. The latch of claim 1, wherein the pulse rejection inverter is configured to receive a sampled logic signal, delay the sampled logic signal, and compare the sampled logic signal to the delayed logic signal.

3. The latch of claim 2, wherein the pulse rejection inverter comprises at least one delay gate for delaying the sampled logic signal.

4. The latch of claim 3, wherein the at least one delay gate has an associated delay time, and wherein delay time is predetermined so that the delay time is longer than a duration associated with a single event transient.

5. The latch of claim 3, wherein the pulse rejection inverter further comprises a series of stacked FETs, and wherein the at least one delay gate is coupled to gate inputs of the stacked FETs.

6. The latch of claim 5, wherein the pulse rejection inverter is configured to allow the delayed logic signal to propagate through the stacked FETs when the sampled logic signal and the delayed logic signal are at a substantially equivalent voltage level.

7. The latch of claim 1, wherein the latch is included in a register.

8. The latch of claim 1, wherein the predetermined phase of the clock signal comprises at least one of a rising edge of the clock signal and a falling edge of the clock signal.

9. The latch of claim 1, wherein the pulse rejection inverter, in operation, mitigates single event transient effects that occur on the clock signal.

10. A method of operating a radiation hardened register, the method comprising:
receiving an input logic signal;
sampling the input logic signal at a first phase of a clock signal;
delaying the sampled logic signal;
comparing the sampled logic signal to the delayed signal; and
if the sampled logic signal and the delayed logic signal are at a substantially equivalent voltage level, propagating the delayed logic signal to an output node of the register.

11. The method of claim 10, further comprising:
if the sampled logic signal and the delayed logic signal are not at a substantially equivalent voltage level, outputting a previously stored logic signal to the output node.

12. The method of claim 10, wherein delaying the sampled logic signal comprises supplying the sampled logic signal to at least one delay gate.

13. The method of claim 12, wherein comparing the sampled logic signal to the delayed combinational signal comprises:
supplying the sampled logic signal to a first gate input of a series of stacked FETs; and
supplying the delayed logic signal to a second gate input of the series of stacked FETs.

14. The method of claim 10, wherein the delay gate has a predetermined delay time that is longer than the duration of a single event transient.

15. A radiation hardened register, comprising:
a master latch coupled to receive an input logic signal and a clock signal, wherein the master latch comprises a first pulse rejection inverter that, in operation, delays the input logic signal and compares delayed logic signal to the input logic signal so that the delayed logic signal propagates through the latch when the delayed logic signal and the input logic signal are at an equivalent voltage level; and
a slave latch coupled to the master latch and coupled to receive the clock signal and the delayed logic signal, wherein, in operation, the slave latch outputs a latched logic signal.

16. The register of claim 15, wherein the master latch comprises a first gate for receiving the input logic signal, sampling the input logic signal, and communicating the input logic signal to the first pulse rejection inverter.

17. The register of claim 15, wherein the first pulse rejection inverter comprises at least one delay gate for delaying the input logic signal.

18. The register of claim 17, wherein the at least one delay gate has an associated delay time, and wherein delay time is predetermined so that the delay time is longer than a duration associated with a single event transient.

19. The register of claim 18, wherein the pulse rejection inverter further comprises a series of stacked FETs, and wherein the at least one delay gate is coupled to gate inputs of the stacked FETs.

20. The register of claim 15, wherein the slave latch further comprises a second pulse rejection inverter that is coupled to receive the delayed logic signal.
